(19) United States
(12) Patent Application Publication
(10) Pub. No.: US 2003/0168009 A1
(43) Pub. Date: Sep. 11, 2003

(54) Plasma processing within low-dimension cavities

(76) Inventors: Ferencz S. Denes, Madison, WI (US); Sorin O. Manolache, Madison, WI (US); Robert J. Sandberg, Verona, WI (US)

Correspondence Address: Intellectual Property Department, DEWITT ROSS & STEVENS, S.C., Firstar Financial Centre, 8000 Excelsior Drive Suite 401, Madison, WI, 53717-1914, US

(21) Appl. No.: 10/382,140

(22) Filed: Mar. 5, 2003

Related U.S. Application Data
(60) Provisional application No. 60/362,658, filed on Mar. 8, 2002.

(51) Int. Cl. C23C 16/00; H01L 21/306

(52) U.S. Cl. 118/718; 118/723 E; 156/345.43; 156/345.47; 216/67; 427/569

(57) ABSTRACT

Methods and apparata for plasma treatment provide a passage through dielectric material, which may be solid material (such as ceramic) or fluid material (such as appropriate liquids or gels). Electrodes are situated outside and adjacent to the passage, and they apply an electric field within the passage to generate plasma from gas traveling within the passage. The object to be plasma treated is situated within the passage, and process gas is supplied (1) to the passage between the exterior of the object and the surface of the passage walls if plasma treatment of the exterior surface of the object is desired; (2) within the interior of the object (as where the object is a hollow tube) if plasma treatment of the interior of the object is desired; or (3) both outside and inside the object and within the passage if plasma treatment of both exterior and interior surfaces is desired.

### CROSS-REFERENCE TO RELATED APPLICATIONS

This application claims priority under 35 USC §119(e) to U.S. Provisional Patent Application No. 60/362,658 filed Mar. 8, 2002, the entirety of which is incorporated by reference herein.

### STATEMENT REGARDING FEDERALLY SPONSORED RESEARCH

This invention was made with United States government support awarded by the following agencies: United States Department of Agriculture, Grant No. USDA 00-51110-9735. The United States has certain rights in this invention.

### FIELD OF THE INVENTION

This disclosure concerns an invention relating generally to plasma generators, and more specifically to “cold” plasma generators and/or plasma generators operating at atmospheric pressure. More specifically still, this disclosure relates to the plasma processing of materials having relatively small size in one or more dimensions, particularly elongated materials such as rods, filaments, and the like, and more particularly where such materials bear internal passages or cavities which are usefully treated with plasma.

### BACKGROUND OF THE INVENTION

Plasma, the fourth state of matter, consists of gaseous complexes in which all or a portion of the atoms or molecules are dissociated into free electrons, ions, free radicals, and neutral particles. On earth, plasma occurs naturally in lightning bolts, flames, and similar phenomena, or may be manufactured by heating a gas to high temperatures, or by applying a strong electric field to a gas, the more common method. The latter type of plasma, often referred to as an electrical discharge plasma, can be further subclassified as a “hot” plasma, i.e., dissociated gas in thermal equilibrium at high temperatures (^{˜}5000 K), or “cold” plasma, i.e., nonthermal plasma wherein the dissociated gas is at low temperatures but its electrons are at high temperature (i.e., in a state of high kinetic energy).

The usefulness of plasma for manufacturing and other applications is best understood by reviewing common applications for cold plasma. As an example, common cold plasma processing methods are commonly used to alter the surface properties of industrial materials without affecting the bulk properties of the treated material. The most common cold plasma surface treatments may be generally categorized as cleaning, activation, grafting, and deposition processes, each of which will now be briefly reviewed.

Plasma cleaning processes typically utilize inert or oxygen plasmas (i.e., plasmas generated from inert or oxygen-based process gases) to remove contaminants (generally organic contaminants) on a material surface subjected to vacuum. The contaminants are exposed to a plasma stream, and they undergo repetitive chain scission from the plasma until their molecular weight is sufficiently low to boil away in the vacuum.

Plasma activation is used when a material (generally a polymer or elastomer) is subjected to a plasma generally produced from an inert or non-carbon gas, and results in the incorporation of different moieties of the process gas onto the surface of the material being treated. For example, the surface of polyethylene normally consists solely of carbon and hydrogen. However, if subjected to an appropriate plasma, the surface may be activated to contain a variety of functional groups which enhance the adhesion and permanence of coatings later applied to the surface. As an example, a surface can be treated to greatly enhance its ability to bond with adhesives.

Deposition, which is exemplified by a process referred to as plasma-enhanced chemical vapor deposition (PECVD), utilizes a complex molecule as the process gas. The process gas molecules are decomposed near the surface to be treated, and recombine to form a material which precipitates onto and coats the surface.

Grafting generally utilizes an inert process gas to create free radicals on the material surface, and subsequent exposure of the radicalized surface to monomers or other molecules will graft these molecules to the surface.

The foregoing cold plasma processes have numerous practical applications, including sterilizing of medical equipment, application of industrial and commercial coatings, etching computer chips, semiconductors, and circuits, and so forth. Hot plasma might be used for generally the same types of applications as cold plasma. However, hot plasma applications are limited since most organic matter cannot be treated under the high temperatures required for hot plasmas without severe degradation. Additionally, hot plasma technology is energy and equipment intensive, making it expensive and difficult to work with. In contrast, cold plasma may be used at temperature ranges as low as room temperature (or lower), making it significantly easier to handle. However, cold plasma processes have the disadvantage that they generally need low pressure conditions to operate (generally a vacuum), and consequently need large, static (i.e., immobile) equipment with a low-pressure treatment chamber to operate. This causes significant manufacturing constraints since the need to treat items within an enclosed chamber makes it inherently difficult to process the items continuously in assembly-line fashion, as opposed to processing the items in batches.

Some of these difficulties have been overcome with further developments in dielectric barrier discharge (DBD) plasma production processes. These processes, which may take place at room temperature and non-vacuum conditions, space a pair of electrodes apart across a free space, with one or more dielectric layers also being situated between the electrode. When an alternating high voltage electrical current is applied to the plates, “microbursts” of plasma are generated from the gas(es) in the free space. DBD apparata are sometimes used to generate ozone by ionizing oxygen passing through the free space of the apparatus, or to break apart volatile gaseous organic compounds passing through the free space.

However, conventional DBD plasma generation apparata are not well suited for surface treatment of workpieces because of the difficulty in transporting the workpieces through the free space without the plasma's interference with the transport mechanism; for example, one generally cannot run a conveyor through the free space. Difficulties with surface treatments are compounded where the surfaces become more difficult to access—for example, where it is desired to treat the interior of a pipe, or the voids within porous material—since conventional plasma generators cannot practically be fit adjacent to such surfaces. Adjacency is an important issue since distant spacing can allow the radicals and other components of the generated plasma to recombine prior to reaching the interior surfaces of the object to be treated.

### SUMMARY OF THE INVENTION

The invention involves methods and apparata for plasma processing which are intended to at least partially solve the aforementioned problems. Following is a brief summary of preferred versions of the methods and apparata to give the reader a basic understanding of some of their advantageous features. As this is merely a summary, it should be understood that more details regarding the preferred versions may be found in the Detailed Description set forth elsewhere in this document. The claims set forth at the end of this document then define the various versions of the invention in which exclusive rights are secured.

A plasma treatment apparatus is provided wherein a passage is defined through dielectric material, which may be solid material (such as ceramic) or fluid material (such as appropriate liquids or gels). Electrodes are situated outside and adjacent to the passage, and they apply an electric field within the passage to generate plasma from gas traveling within the passage. The object to be treated with plasma is supplied to the passage, preferably continuously, as by feeding it through the passage from a coil. Alternatively, the object may simply rest within the passage throughout treatment, e.g., by simply situating the object (in coiled or other form) within the passage. Gas may be supplied to the passage between the exterior of the object and the surface of the passage walls, for treatment of the exterior surface of the object; within the interior of the object (as where the object is a hollow tube or other structure having a defined interior surface), for treatment of the interior surface of the object; or both outside and inside the object and within the passage. Preferably, no conveyors or other mechanisms for transporting the object are provided within the passage, particularly at the region(s) of the passage adjacent to the electrodes, so that only the object and the gas are situated within the passage adjacent to the electrodes. Instead, when the object is to be continuously supplied to the passage, the object is provided to (and through) the passage by rollers, feeders, conveyors, or other transport mechanisms which are preferably situated outside of the passage, and which preferably supply the object along the center of the passage with the exterior of the object traveling along, or slightly spaced from, the passage walls. The passage walls are preferably shaped complementary to the exterior of the object so the exterior of the object closely fits, or is closely spaced from, the passage walls.

The invention is particularly useful for plasma treatment of the exterior surfaces of elongated strands of material, or the exterior and/or interior surfaces of strands of material which have a tubular configuration. Where exterior surfaces are to be treated, the strand(s) are simply fed through the passage(s) with the gas situated about the strand(s). Where interior surfaces of tubular strands are to be treated, the strand(s) are fed through the passage(s) with the gas provided within the interior(s) of the strand(s). Simultaneous treatment of interior and exterior surfaces are possible, and different gases may be used adjacent the interior and exterior surfaces to achieve different functionalities or other goals.

When interior surfaces are to be treated, certain advantages are provided where the dielectric material is a fluid, since the dielectric will fluidly conform to the outer surface of the object as it is supplied through the dielectric and the gas is supplied through the interior of the object. In other words, the object will define the passage as it travels through the dielectric.

Further advantages, features, and objects of the invention will be apparent from the following detailed description of the invention in conjunction with the associated drawings.

### BRIEF DESCRIPTION OF THE DRAWINGS

FIG. 1 is a simplified cross-sectional elevational view of a plasma processing apparatus 100 wherein an object 10, which is provided in the form of a tubular strand, is fed from an infeed coil 114 through fluid dielectric 104 to undergo plasma treatment between electrodes 106A and 106B.

FIG. 2 is a simplified cross-sectional elevational view of the infeed coil 114 of FIG. 1 illustrating the supply of process gas to the interior of the object 10 prior to its entry into the process chamber 102 of the plasma processing apparatus 100.

FIG. 3 is a simplified cross-sectional elevational view of the reaction chamber 102 of FIG. 1, as viewed from a plane perpendicular to the length of the object 10 in FIG. 1, illustrating how several objects 10 (or several lengths of the same object 10) may be simultaneously treated between electrodes 106A and 106B.

FIG. 4 is a simplified cross-sectional elevational view of a plasma processing apparatus 400 wherein the object 10 is processed on a coil 414 situated between electrodes 406A and 406B.

FIG. 5 is a simplified cross-sectional elevational view of a plasma processing apparatus 500 wherein the object 10 is processed within a passage 520 within solid dielectric material 504 wherein electrodes 406A and 406B are embedded.

### DETAILED DESCRIPTION OF PREFERRED EMBODIMENTS OF THE INVENTION

Initially referring to FIG. 1, a first preferred version of the invention is depicted generally by the reference numeral 100. A reaction chamber 102 contains an amount of fluid dielectric material such as polydimethylsiloxane, paraffin oil, hydrocarbon oil, fluorinated hydrocarbon pump oil, ultra-pure water, or other dielectric in liquid, gel, or similar form. A pair of charged electrodes 106A and 106B are immersed within the dielectric material 104, with electrode 106A being shown attached to a high voltage power supply 108 and electrode 106B being shown attached to ground 110. Rollers 112 supply the object 10 to be treated with plasma, here a tubular strand material such as plastic tubing or glass capillary tubing, from an infeed coil 114 to a take-up coil 116. The rollers 112 transport the object 10 between the coils 114 and 116, and through the dielectric material 104 of the reaction chamber 102 and between the electrodes 106A and 106B. Because the dielectric material 104 is fluid and will conform to the shape of the exterior surface of the object 10, the object displaces the dielectric material to define its own passage through the dielectric material 104, with the interior of the tubular object 10 extending between the electrodes 106A and 106B along the passage.

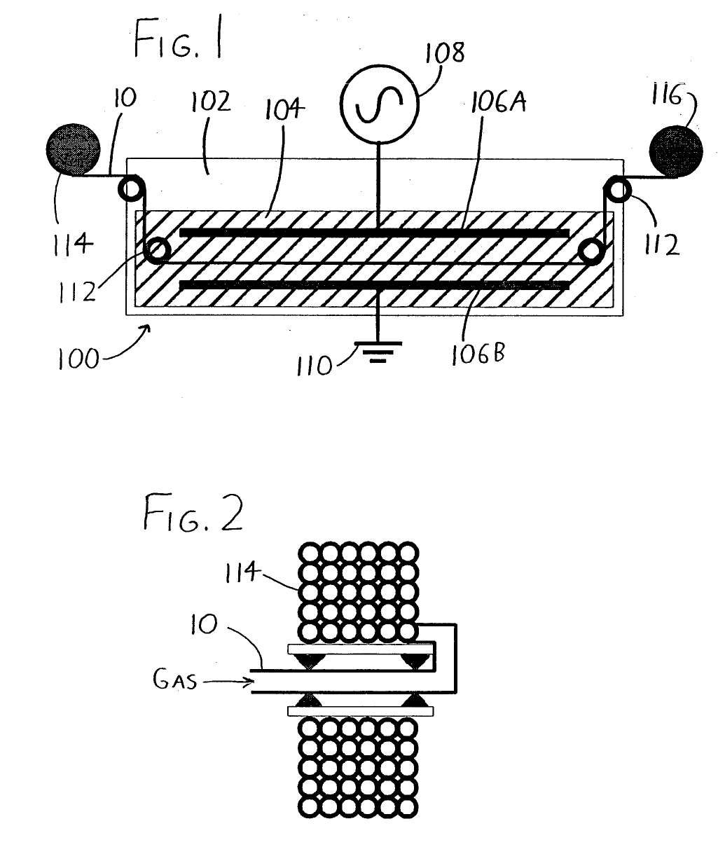

Process gas may then be supplied to the interior of the object 10, as by feeding process gas into one of the ends of the object 10 situated at the axis of the infeed coil 114 (as depicted in FIG. 2). The process gas will therefore travel through the passage defined within the interior of the object 10 between the electrodes 106A and 106B. Appropriate voltages and frequencies may be applied to the electrodes 106A and 106B (generally 10 kilovolts or higher and 10 kilohertz or higher) to generate plasma from the process gas within the interior of the object 10, for the purposes of cleaning and/or functionalization/modification of the interior surface. The rollers 112, which serve as the transport mechanism for transporting the object 10 through the dielectric material 104 and between the electrodes 106A and 106B, are not situated between the electrodes 106A and 106B and do not interfere with plasma generation. Other transport mechanisms may be used, or the transport mechanisms may be omitted, depending on the nature of the object 10 to be treated; for example, where more rigid objects 10 are to be processed, the rollers 112 might be omitted and the object 10 and might simply be placed between the electrodes 106A and 106B, or the rollers 112 might feed the object 10 along a linear path.

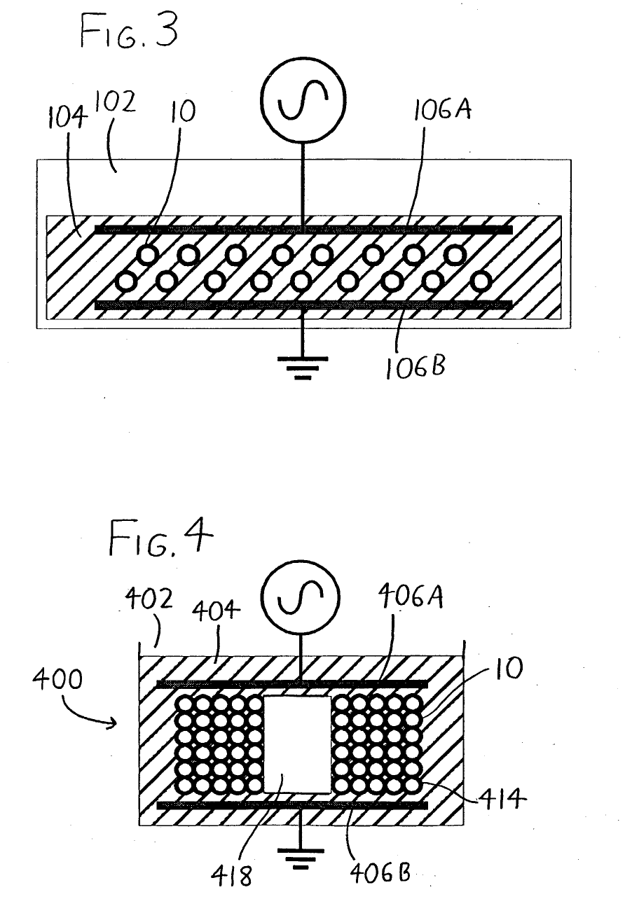

It is possible for the same coils 114 and 116, or for multiple infeed and take-up coils 114 and 116, to feed multiple lengths of the object 10 into the reaction chamber 102 at the same time. An exemplary arrangement of this nature is depicted in FIG. 3, which provides a view within the reaction chamber 102 of FIG. 1 from a plane perpendicular to the length of the object 10. Here, multiple lengths of the object 10 are simultaneously provided to the reaction chamber 102, and these lengths could be situated on the same object 10 or on different objects 10. It is noted that the apparatus 100 need not be operated in continuous mode with the object being continuously fed into the reaction chamber 102, and could instead be operated in batch mode, wherein new lengths of object 10 are supplied to the reaction chamber 102 at discrete intervals of time.

The shapes, sizes, and spacing of the electrodes 106A and 106B, the reaction chamber 102, the rollers 112, etc. can vary depending on the dimensions and the desired speed of the plasma processing of the object 10, as well as the number of lengths of the object 10 that are to be treated at the same time. It is desirable for the electrodes 106A and 106B to be mounted spaced apart in such a manner that they are at least substantially parallel, or else selective discharge may occur in those areas where the electrodes 106A and 106B are spaced closer together. Additionally, while the electrodes 106A and 106B in FIGS. 1 and 3 are depicted as being flat plates, as will be discussed in later examples, it is desirable to round any corners provided on the electrodes 106A and 106B to avoid edge effects and prevent selective discharge at corner regions. As an example, the flat plate electrodes 106A and 106B could instead be provided in rodlike/cylindrical form (e.g., as cylindrical wire leads), with the cylinders extending parallel to the lengths of the object 10 within the dielectric material 104, and with their leads gradually curving out of the reaction chamber 102 at the ends of the electrodes 106A and 106B so that selective discharge will not arise from any discontinuities present where the leads contact the electrodes.

Arrangements such as the apparatus 100 advantageously allow for the controlled modification of interior surfaces of objects 10 to provide specific properties, including hydrophobic and hydrophilic surfaces, plasma functionalized surfaces, covalent attachment of active biomolecules (e.g., enzymes, biotin, antibodies, heparin, oligos, etc.), as well as the disinfection and decontamination of interior surfaces for biotech, medical, or other applications. The apparatus 100 allows for easy and uniform supply of process gas through the object 10, and generation of a uniform discharge within the object 10, for consistent treatment of interior surfaces. The apparatus 100 additionally allows simultaneous processing of one or more lengths of the object 10, in batch or continuous fashion. Use of the fluid dielectric 104 is also advantageous in that it may be easily heated or cooled by providing an appropriate heater, cooler, or heat exchanger within the dielectric 104, or by circulating the dielectric 104 through such a device. If necessary or desirable, the object 10 can also travel through a solvent bath (not shown) prior to being wound onto the take-up coil 116, or after being wound on the take-up coil 116, to remove any dielectric material 104 which remains on the exterior surface of the object 10.

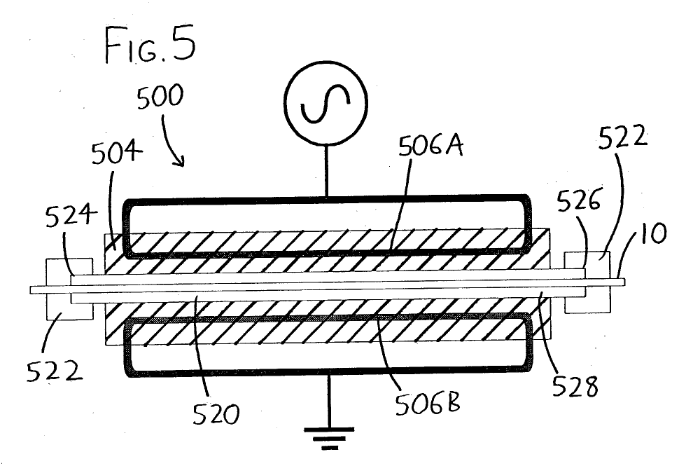

FIG. 4 illustrates another arrangement, designated generally by the reference numeral 400, wherein the charged electrodes 406A and 406B are again provided within a chamber 402 containing fluid dielectric material 404, but wherein the object 10 is situated between the electrodes 406A and 406B on a coil 414. Here, process gas may be passed through the length of the interior of the object 10 while the electrodes 406A and 406B are charged, allowing treatment of extremely long lengths of the interior surface of the object 10 within a compact space. The object 10 is wound about a dielectric core 418 about which the electrodes 406A and 406B are spaced. If some arrangement for holding the coil 414 in place between the electrodes 406A and 406B is needed, the core 418 might extend between the electrodes 406A and 406B to maintain the coil 414 therebetween, or alternatively the electrodes 406A and 406B might bear apertures adjacent the core 418 through which a dielectric spindle is provided to the core 418, with the spindle either rotationally driving the core 418 (and coil 414) or otherwise maintaining it stationary. Advantageously, the arrangement 400 allows multi-step plasma processes to be easily implemented by varying the process gases supplied to the object 10. (Stepping back to FIGS. 1-3, while the process gases 10 could also be varied within the apparatus 100 to allow for multi-step processing, the residence time of the object 10 within the apparatus 100 may not be sufficiently long that multi-step processing is feasible, unless the reaction chamber 102 is very long, the speed of travel of the object 10 through the reaction chamber 102 is low, and/or the apparatus 100 is run in batch mode rather than continuous mode.) During plasma processing within the apparatus 400, the coil 414 may be stationary (i.e., the object 10 is treated in batch fashion), or the coil 414 may continuously reel in new lengths of the object 10 to be treated, and spool treated lengths of the object 10 out of the dielectric material 404.

A comparison of the apparatus 400 with the apparatus 100 demonstrates that the object 10, so long as it is flexible, need not follow a linear path through the dielectric material. As FIGS. 3 and 4 illustrate, multiple lengths of the same or different objects 10 may be simultaneously processed within an extremely compact space by providing the object(s) within the dielectric in an arrangement wherein the lengths of the object(s) are adjacently or closely spaced in at least substantially parallel relationship, thereby allowing significant lengths of the object(s) to fit within a smaller reaction chamber.

FIG. 5 illustrates another exemplary version of the invention where the apparatus 500 does not use a fluid dielectric material, and instead uses a solid dielectric material 504 having the passage 520 defined therein so that the walls of the passage 520 are rigidly defined by the dielectric material 504. The electrodes 506A and 506B are here illustrated in the preferred form of conductors having rodlike/cylindrical lengths which extend into the dielectric material 504. The electrodes 506A and 506B lack any defined corners, and they gently curve towards the passage 520 and then gently curve away so as to reduce the possibility of selective discharge. The passage 520 may simply be drilled or otherwise formed in the dielectric material 504, or it may be cast about a dielectric tube 528 (which may be made of glass or similar materials) by use of curable dielectric polymeric 15 materials such as epoxides, silicon rubber, acrylics, etc. After the dielectric material 504 cures, the tube 528 may be broken out or otherwise removed, if desired. It is notable that there are a number of ways to form a passage 520 within solid dielectric material 504 apart from the foregoing methods, so the foregoing methods should not be regarded as the only forms that the apparatus 500 may assume; for example, the dielectric tube 528 may have the electrodes 506A and 506B situated in grooves machined within the exterior surfaces of the tube 528 (and bonded therein using curable dielectric materials if desired). Advantageously, the use of a solid dielectric material 504 allows the solid dielectric material 504 to serve as the support for the electrodes 506A and 506B, helping to maintain them in at least substantially parallel alignment (and parallel to the passage 520).

To use the apparatus 500, the object 10 may be fed into or otherwise situated within the passage 520 as discussed previously, and process gas may be provided to the interior of the object 10 (if the object 10 has a hollow interior) for interior plasma treatment of the object 10 in the manner previously described. However, the apparatus 500 also or alternatively allows plasma treatment of the exterior surface of the object 10. Process gas chambers 522 may be situated at or near the passage entry 524 and the passage exit 526 so that process gas supplied to one or both of the gas chambers 522 will flow through the passage 520 alongside the exterior surface of the object 10, thus allowing plasma treatment of the exterior of the object 10 when the electrodes 506A and 506B are charged. Assuming the object 10 has an interior surface, both the interior and exterior surfaces of the object 10 may be plasma treated at the same time by providing the desired process gases within the passage 520 surrounding the exterior of the object 10, and also within the interior of the object 10. Further, the process gases need not be the same, and may be chosen to fulfill different purposes or provide different functionality on the interior and exterior surfaces of the object 10.

If only the exterior surface of the object 10 is to be treated, the interior of the object 10 (assuming the object 10 is hollow rather than solid) may be evacuated, filled with a nonreactive gas or dielectric fluid, or otherwise adapted so that no interior plasma treatment need occur. Alternatively, if only the interior surface of the object 10 is to be treated, exterior treatment can be avoided by sizing the passage 520 such that the exterior of the object 10 essentially abuts the walls of the passage 520, or the passage 520 surrounding the exterior of the surface of the object 10 might be filled with dielectric fluid, a nonreactive gas, etc. so that plasma treatment only occurs within the interior of the object 10. So long as the exterior surface of the object 10 abuts or is closely spaced from the walls of the passage 520, discharges and plasma generation between the exterior surface of the object 10 and the walls of the passage 520 will be diminished or negligible.

When the apparatus 500 is in use for continuous processing of the object 10 (i.e., the object 10 is continuously fed through the passage 520), it can be difficult to seal the gas chambers 522 about the entering and exiting object 10 to make the gas chambers 522 absolutely airtight with respect to the exterior atmosphere. Where the object 10 has an outer surface having a cylindrical cross-section, elastomeric gaskets have been provided in the gas chambers 522 at the regions where the object 10 enters and exits, with the gaskets providing circular ingress and egress holes which frictionally fit about the object 10. However, this type of sealing arrangement can be more difficult to effectively accomplish if the object 10 has an outer surface with a cross-sectional shape of greater complexity. This difficulty can be avoided by enlarging the gas chambers 522 and situating the infeed and take-up coils (or other supply structures) within the gas chambers 522 themselves. However, unless the process gases pose an environmental hazard, it is not necessary that the gas chambers 522 be absolutely airtight; rather, all that is necessary is that the gas chambers 522 provide positive pressure with respect to the external atmosphere, so that atmospheric gases do not enter the passage 520 and contaminate the process gases with atmospheric gases, and instead the process gases vent outwardly from the gas chambers 522 to the atmosphere. If the atmospheric gases are desirable or have negligible effect on the plasma treatment, sealing and/or the use of positive pressure is not necessary.

The ability of the apparatus 500 to simultaneously treat the interior and exterior surfaces of tubular materials is extremely useful, particularly in the biotech and biomedical fields. As examples, the apparatus 500 can be used to treat capillaries so that they are externally sterilized, and internally functionalized with an antifouling coating, for use as catheters, in blood plasma testing applications, etc. Even where internal treatment of the object 10 is not used, the apparatus 500 is extremely useful for the treatment of exterior surfaces of objects 10. As an example, cords or bundles made of polyethylene, polypropylene, polyamide, polyester, or other materials may be surface functionalized so that when placed within matrices to form a composite material, their surfaces better adhere to the matrices. As another example, metallic thin layers may be deposited on onto such strands/bundles to generate strands/bundles with unique electromagnetic, optical, and/or biological properties.

Where exterior surfaces of objects 10 are to be treated, it is highly desirable to have the walls of the passage 520 be shaped complementary to the object 10 which is provided within the passage 520, so that the walls of the passage 520 adjacent each point on the exterior surface of the object 10 are spaced approximately the same short distance away from the exterior surface of the object 10. This helps maintain the quality and uniformity of the partial discharges (and the plasma generation) occurring within the gap situated between the exterior surface of the object 10 and the walls of the passage 520. While the apparatus 500 is particularly well suited for treatment of objects 10 having small external diameters—less than 2 cm or so—objects 10 having exterior surfaces with larger diameters could be processed as well. However, there are some practical limitations on the size of the objects 10 that may be treated, since the farther apart the electrodes 506A and 506B are spaced, the greater the voltage that must be supplied to the electrodes 506A and 506B. The plasma treatment of interior surfaces of the object 10 also grows more difficult as the diameter of the interior surface grows, not merely owing to the spacing of the electrodes, but also because plasma generated within a large interior space might reach equilibrium before significant contact with the interior surface occurs. Ideally, it is useful to have the process gas travel within a small space adjacent the surface to be treated. Thus, for treatment of large interior spaces, the effective size of the interior of the object 10 may be reduced by (for example) coaxially inserting a plug or mandrel into the object 10 so that the process gas travels in a narrow channel adjacent to the interior surface of the object 10 (though this arrangement can be difficult to achieve where the object 10 is being continuously fed into the apparatus 500). As another example, dielectric fluid, or dielectric bearings or other fillers, can ride within the interior of the object 10 and partially occupy the internal volume of the object 10 during plasma treatment. If this approach is used, the object 10 can periodically be rotated about its axis (or the orientation of the object 10 can otherwise be changed) so that the fillers change their position within the object 10 over time, so that all portions of the interior surface of the object 10 will be placed in contact with the process gas at some time during the treatment process.

It is desirable to have the electrodes have a channel formed therein for circulation of cooling media (e.g., liquid nitrogen or cooled gases), or heating media (e.g., heated gases), to allow cooling or heating of the electrodes when desired. In versions of the invention such as in FIG. 5, where the electrodes are cylindrical, such channels may be easily provided by simply using hollow tubing for the electrodes and cycling heated or cooled air, or liquefied gases, through the electrodes.

It is understood that the various preferred versions of the invention are shown and described above to illustrate different possible features of the invention and the varying ways in which these features may be combined. Apart from combining the different features of the foregoing versions in varying ways, other modifications are also considered to be within the scope of the invention. Following is an exemplary list of such modifications.

First, throughout this document, it should be understood that the term “process gas” includes not merely pure gases, but also gas mixtures and gases containing vapors, monomers, or other substances, as is typical in plasma processing techniques.

Second, where this document refers to objects 10 which are formed as tubes, such objects need not have a cylindrical inner surface (i.e., the objects 10 need not be cylindrical tubes). The invention may be utilized to treat the interior and/or exterior surfaces of tubing having square cross-sections or cross-sections of other shapes. Channels or other depressions formed on exterior surfaces of objects may also be treated, either alone or in conjunction with the treatment of the remainder of the exterior surface of an object. Portions of exterior surfaces which are not to be treated can be “masked” by having these portions abut the passage wall when they travel therein, by applying removable masking layers prior to plasma treatment, or by other methods whereby the areas which are not to be treated are protected from exposure to the process gas.

Third, while the invention has been generally described for use in the processing of elongated objects, including elongated objects with elongated interior surfaces, it can also be used for the processing of objects having other shapes. As an example, MEMS (Micro-Electro-Mechanical Systems) devices often include channels/passages for the purpose of receiving substances to be treated or analyzed (e.g., in capillary electrophoresis), for heating/cooling, or for other applications. Such passages may be treated with plasma by appropriately configuring the passage through the dielectric material so that the MEMS device may be received within the passage, and process gas may be fed into and/or through the channels. The devices may alternatively be received within a dielectric tray or other carrier which is received within the passage, and from which the device may be removed after plasma treatment has been applied. For example, if the MEMS devices have channels/passages which are aligned (i.e., the entry of a channel/passage on one device abuts the exit of a channel/passage on another device) when the devices are arrayed in a row on a tray or other carrier, the carrier may simply be sent through the passage in the dielectric material and the process gas may be supplied through the combined channels/passages of the device. Alternatively, the tray or other carrier might receive the MEMS devices within sockets, and the regions of the carrier adjacent the socket may bear communicating channels/passages which direct process gas as desired to the channels/passages of the MEMS devices within the sockets.

Note that preferred versions of the invention have been described above in order to illustrate how to make and use the invention. The invention is not intended to be limited to these versions, but rather is intended to be limited only by the claims set out below. Thus, the invention encompasses all different versions of the invention that fall literally or equivalently within the scope of these claims.

What is claimed is:

1. An apparatus for plasma treatment of an object, the apparatus comprising:
a. dielectric material having a passage defined therein, the passage being bounded by a passage entry, a passage exit, and passage walls extending between the passage entry and passage exit;
b. a pair of charged electrodes situated outside and adjacent to the passage;
c. a gas supply supplying gas to the passage;
wherein solely the object and the gas are situated in the passage adjacent to the electrodes.

2. The apparatus of claim 1 wherein the gas surrounds the object within the passage adjacent to the electrodes.

3. The apparatus of claim 1 wherein the gas is situated between the object and the passage walls adjacent to the electrodes.

4. The apparatus of claim 1 wherein:
a. the object has an interior surface and an exterior surface, the interior surface bounding an interior, and
b. the gas is supplied to the interior of the object.

5. The apparatus of claim 4 wherein a second gas is supplied within the passage and outside the exterior surface of the object.

6. The apparatus of claim 4 wherein the passage walls abut the exterior surface of the object.

7. The apparatus of claim 4 wherein the passage walls fluidly conform to the shape of the exterior surface of the object.

8. The apparatus of claim 1 wherein:
a. the object has an interior surface and an exterior surface, the interior surface bounding an interior,
b. the interior does not open onto the passage, and
c. the gas is supplied to the interior of the object.

9. The apparatus of claim 8 wherein a second gas is supplied within the passage and outside the exterior surface of the object.

10. The apparatus of claim 8 wherein the passage walls abut the exterior surface of the object.

11. The apparatus of claim 8 wherein the passage walls fluidly conform to the shape of the exterior surface of the object.

12. The apparatus of claim 1 wherein the dielectric material is a fluid.

13. The apparatus of claim 1 wherein the electrodes are embedded within the dielectric adjacent the passage.

14. The apparatus of claim 1 wherein at least a portion of the electrodes is situated within the dielectric material, and wherein any portion of the electrodes located within the dielectric material lacks any defined corners.

15. The apparatus of claim 1 wherein the object is supplied to the passage entry from a coil.

16. The apparatus of claim 1 wherein the object is elongated, and wherein two or more lengths of the object are situated in at least substantially parallel relationship within the dielectric material and between the electrodes.

17. The apparatus of claim 1 wherein:
a. the object is elongated and has its length oriented along the passage,
b. the object has an object profile defined in a plane perpendicular to the object's length, and
c. the passage walls adjacent the electrodes are shaped complementary to the object profile.

18. The apparatus of claim 17 wherein the passage walls adjacent the electrodes fluidly conform to the object profile.

19. The apparatus of claim 1 wherein:
a. the object is elongated and has its length oriented along the passage,
b. the passage adjacent to the electrodes follows a nonlinear path.

20. The apparatus of claim 19 wherein the object is flexible.

21. The apparatus of claim 19 wherein the dielectric material is a fluid which fluidly conforms to the outer surface of the object.

22. The apparatus of claim 19 wherein the path of the passage adjacent to the electrodes orients portions of the length of the object into at least substantially parallel alignment.

23. A method for plasma treatment of an object comprising the steps of:
a. providing a passage within dielectric material, the passage being bounded by a passage entry, a passage exit, and passage walls extending between the passage entry and passage exit, and wherein a pair of charged electrodes is situated outside and adjacent to the passage;
b. transporting the object through the passage; and
c. supplying gas to the passage,
wherein solely the object and the gas are situated in the passage adjacent to the electrodes.

24. The method of claim 20 wherein the gas surrounds the object when the object is transported through the passage adjacent to the electrodes.

25. The method of claim 20 wherein the gas is situated between the object and the passage walls when the object is transported through the passage adjacent to the electrodes.

26. The method of claim 23 wherein:
a. the object has an interior surface and an exterior surface, the interior surface bounding an interior,
b. the interior does not open onto the passage, and
c. the gas is supplied to the interior of the object.

27. The method of claim 26 wherein a second gas is supplied within the passage and outside the exterior surface of the object.

28. The method of claim 26 wherein the passage walls abut the exterior surface of the object.

29. The method of claim 26 wherein the passage walls fluidly conform to the shape of the exterior surface of the object.

30. The method of claim 23 wherein the dielectric material is a fluid.

31. The method of claim 23 wherein the electrodes are embedded within the dielectric adjacent the passage.

32. The method of claim 23 wherein at least a portion of the electrodes is situated within the dielectric material, and wherein any portion of the electrodes located within the dielectric material lacks any defined corners.

33. The method of claim 23 wherein the object is supplied to the passage entry from a coil.

34. The method of claim 23 wherein the object is elongated, and wherein two or more lengths of the object are situated in at least substantially parallel relationship within the dielectric material and between the electrodes.

35. The method of claim 23 wherein:
a. the object is elongated and has its length oriented along the passage,
b. the object has an object profile defined in a plane perpendicular to the object's length, and
c. the passage walls adjacent the electrodes are shaped complementary to the object profile.

36. The method of claim 23 wherein:
a. the object is elongated and has its length oriented along the passage,
b. the passage adjacent to the electrodes follows a nonlinear path.

37. The method of claim 36 wherein the path of the passage adjacent to the electrodes orients portions of the length of the object into at least substantially parallel alignment.

38. An apparatus for plasma treatment of an object, the apparatus comprising:
a. fluid dielectric material having a passage extending therein;
b. electrodes situated outside the passage;
c. a gas supply supplying gas to the passage;
wherein the object is situated within the passage adjacent to the electrodes.

39. The apparatus of claim 38 wherein the object has an interior passage into which the gas is supplied.

40. The apparatus of claim 38 wherein the passage is defined by the outer surface of the object, and wherein the object has an interior passage into which the gas is supplied.

41. The apparatus of claim 38 wherein the passage is defined by walls which fluidly conform to the shape of the exterior surface of the object.

42. The apparatus of claim 38 wherein the object is supplied to the passage from a coil.

43. The apparatus of claim 38 wherein the path of the passage adjacent to the electrodes orients portions of the length of the object into at least substantially parallel alignment.

44. The apparatus of claim 38 wherein the object is elongated, and wherein two or more lengths of the object are situated in at least substantially parallel relationship within the dielectric material and between the electrodes.

45. The apparatus of claim 38 wherein:
a. the object is elongated and has its length oriented along the passage,
b. the passage adjacent to the electrodes follows a nonlinear path.

46. The apparatus of claim 38 wherein the object is flexible.
